(19) United States
(12) Patent Application Publication
(10) Pub. No.: US 2022/0120938 A1
(43) Pub. Date: Apr. 21, 2022

(54) LASER CRYSTALLIZATION APPARATUS AND LASER CRYSTALLIZATION METHOD USING THE SAME

(71) Applicant: Samsung Display Co., LTD., Yongin-si (KR)

(72) Inventors: Dong Eon Lim, Cheonan-si (KR); Kyong Sik Choi, Asan-si (KR); Kwang-Jun Koo, Hwaseong-si (KR); Jeong-Mok Kim, Asan-si (KR)

(73) Assignee: Samsung Display Co., LTD., Yongin-si (KR)

(21) Appl. No.: 17/379,484

(22) Filed: Jul. 19, 2021

(30) Foreign Application Priority Data
Oct. 16, 2020 (KR) 10-2020-0134335

(51) Int. Cl. G02B 3/00; H01L 21/02

(52) U.S. Cl. CPC G02B 3/0062; G02B 3/005; H01L 21/02422; H01L 21/02691; H01L 21/02532; H01L 21/02678

(57) ABSTRACT

A laser crystallization apparatus includes light sources that emit a first laser beam and a second laser beam; a first beam homogenizer through which the first laser beam passes; a second beam homogenizer through which the second laser beam passes; and an optical array on which the first laser beam passed through the first beam homogenizer and the second laser beam passed through the second beam homogenizer are incident. A first path of the first laser beam passed through the first beam homogenizer and a second path of the second laser beam passed through the second beam homogenizer are different from each other. The first beam homogenizer includes first lenses having a first pitch. The second beam homogenizer includes second lenses having a second pitch. The first pitch of the first lenses and the second pitch of the second lenses are same each other.

### CROSS-REFERENCE TO RELATED APPLICATION(S)

This application claims priority to and benefits of Korean Patent Application No. 10-2020-0134335 under 35 U.S.C. § 119 filed on Oct. 16, 2020 in the Korean Intellectual Property Office, the entire contents of which are incorporated herein by reference.

### BACKGROUND

### 1. Technical Field

The disclosure relates to a laser crystallization apparatus and a laser crystallization method.

### 2. Description of the Related Art

A liquid crystal display (LCD) and an organic light emitting display (OLED), which are flat panel displays, are widely used as display devices for portable electronic devices as they can be down-sized and light-weight, and they are widely used as display devices for large areas. In recent years, the need for a display device requiring high-speed operation characteristics has emerged, and research thereon is being actively conducted.

In order to satisfy the high-speed operation characteristics, a channel portion of a thin film transistor is formed by using polysilicon instead of amorphous silicon.

As a method of forming polysilicon, an annealing method using a laser has been disclosed.

On the other hand, as a size of a glass substrate for forming a liquid crystal display (LCD) increases, the laser output energy needs to be increased, and it is important that the laser beam profile is uniformly irradiated to improve the quality of laser crystallization.

The above information disclosed in this background section is only for enhancement of understanding of the background of the described technology, and therefore it may contain information that does not form the prior art that may already be known to a person of ordinary skill in the art.

### SUMMARY

Embodiments provide a laser crystallization apparatus that can improve a uniform profile of a laser beam and a laser crystallization method.

It is apparent that objects of the embodiments are not limited to the above-described objects, and can be variously modified within the spirit and the scope of the disclosure.

A laser crystallization apparatus according to an embodiment may include a plurality of light sources that emit a first laser beam and a second laser beam; a first beam homogenizer through which the first laser beam passes, a second beam homogenizer through which the second laser beam passes; and an optical array on which the first laser beam passed through the first beam homogenizer and the second laser beam passed through the second beam homogenizer are incident, wherein a first path of the first laser beam passed through the first beam homogenizer and a second path of the second laser beam passed through the second beam homogenizer may be different from each other, the first beam homogenizer may include first lenses disposed to have a first pitch along a first direction, the second beam homogenizer may include second lenses disposed to have a second pitch along the first direction, and the first pitch of the first lenses and the second pitch of the second lenses may be same each other.

A number of the first lenses and a number of the second lenses may be different from each other.

One of the number of the first lenses and the number of the second lenses may be an odd number, and the other of the number of the first lenses and the number of the second lenses may be an even number.

A difference between the number of the first lenses and the number of the second lenses may be one.

A central axis of each of the first lenses and a central axis of each of the second lenses may be different from each other.

A difference between the central axis of the first lenses and the central axis of the second lenses may be less than the first pitch of the first lenses.

The central axis of the first lenses may be different from the central axis of the second lenses.

A difference between the central axis of the first lenses and the central axis of the second lenses may be less than the first pitch of the first lenses.

A laser crystallization apparatus according to an embodiment may include a plurality of light sources that emit a first laser beam and a second laser beam; a first beam homogenizer through which the first laser beam passes; and a second beam homogenizer through which the second laser beam passes; and an optical array on which the first laser beam passed through the first beam homogenizer and the second laser beam passed through the second beam homogenizer are incident, wherein a first path of the first laser beam passed through the first beam homogenizer and a second path of the second laser beam passed through the second beam homogenizer may be different from each other, the first beam homogenizer may include first lenses disposed along a first direction, and the second beam homogenizer may include second lenses disposed along a second direction, and a path converter.

The first lenses may be disposed to have a first pitch, the second lenses may be disposed to have a second pitch, and the first pitch of the first lenses and the second pitch of the second lenses may be same each other.

A surface of the path converter may be aligned to form a constant angle with a path of the second laser beam.

A laser beam crystallization method according to an embodiment may include irradiating a laser beam from light sources that include a first light source and a second light source; adjusting a first path of a first laser beam irradiated from the first light source to be different from a second path of a second laser beam irradiated from the second light source; and controlling the first laser beam having passed through the first beam homogenizer and the second laser beam having passed through the second beam homogenizer to be incident upon an optical array.

The adjusting of the first path of the first laser beam and the second path of the second laser beam to be different from each other may include controlling the first laser beam pass through the first beam homogenizer that may include first lenses disposed to have a first pitch along a first direction; controlling the second laser beam to pass through the second beam homogenizer that includes second lenses disposed to have a second pitch along a second direction, wherein the first pitch of the first lenses and the second pitch of the second lenses may be same each other.

The controlling of the first laser beam to pass through the first beam homogenizer may include controlling the first laser beam to pass through a first number of the first lenses, and the controlling of the second laser beam to pass through the second beam homogenizer may include controlling the second laser beam to pass through a second number of the second lenses.

One of the first number of the first lenses and the second number of the second lenses may be an odd number, and the other of the first number of the first lenses and the second number of the second lenses may be an even number.

A difference between the first number of the first lenses and the second number of the second lenses may be one.

The controlling of the first laser beam to pass through the first beam homogenizer may include controlling the first laser beam to pass through the first lenses, the controlling of the second laser beam to pass through the second beam homogenizer may include controlling the second laser beam to pass through the second lenses, and a central axis of each of the first lenses may be different from a central axis of each of the second lenses.

A difference between the central axis of the first lenses and the central axis of the second lenses may be less than the first pitch of the first lenses.

The adjusting of the first path of the first laser beam and the second path of the second laser beam to be different from each other may include controlling the first laser beam to pass through the first beam homogenizer that includes first lenses disposed to have a first pitch along a first direction; and controlling the second laser beam to pass through the second beam homogenizer that includes second lenses disposed to have a second pitch along the first direction, and a path converter, wherein the first pitch of the first lenses and the second pitch of the second lenses may be same each other.

A surface of the path converter may be aligned to form a constant angle with a path of the second laser beam, and the second laser beam may pass through the path converter.

It is apparent that the effect of the embodiments is not limited to the above-described effect, and can be variously extended in a range not departing from the spirit and region of the embodiments.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a laser crystallization apparatus according to an embodiment.

FIG. 2 shows a part of the laser crystallization apparatus of FIG. 1.

FIG. 3 shows an optical path conversion member and an optical path of the laser crystallization apparatus according to an embodiment.

FIG. 4 shows a portion of the optical path conversion member of the laser crystallization apparatus according to an embodiment.

FIG. 5 shows a path of the laser beam having passed through the laser crystallization apparatus according to an embodiment.

FIG. 6 shows a path of the laser beam having passed through the laser crystallization apparatus according to an embodiment.

FIG. 7 illustrates a part of a laser crystallization apparatus according to an embodiment.

FIG. 8 and FIGS. 9 (a) and 9 (b) show operation of the laser crystallization apparatus according to an embodiment.

FIGS. 10 (a), (b), and (c) show a path of a laser beam passing through a laser crystallization apparatus according to an embodiment.

FIG. 11 shows a laser crystallization method according to an embodiment.

FIG. 12 is a graph illustrating a result of an experimental example.

FIG. 13 is a graph illustrating a result of an experimental example.

### DETAILED DESCRIPTION OF THE EMBODIMENTS

The disclosure will be described more fully hereinafter with reference to the accompanying drawings, in which embodiments are shown. As those skilled in the art would realize, the described embodiments may be modified in various different ways, all without departing from the spirit or scope of the disclosure.

The drawings and description are to be regarded as illustrative in nature and not restrictive. Like reference numerals designate like elements throughout the specification.

In the drawings, sizes and thicknesses of each element are arbitrarily illustrated for convenience of description, and the disclosure is not necessarily limited to that which is illustrated in the drawings. In the drawings, the thickness of layers, films, panels, regions, etc., are exaggerated for clarity. In addition, in the drawings, for better understanding and ease of description, the thicknesses of some layers and regions are exaggerated.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on a side opposite to the direction of gravity.

In addition, unless explicitly described to the contrary, the word “comprise” and variations such as “comprises” or “comprising”, “include” and variations such as “includes” or “including”, “has” and variations such as “have” or “having” will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from a side.

Throughout the specification, “connected” does not mean only when two or more constituent elements are directly connected, but also when two or more constituent elements are indirectly connected through another constituent element, or when physically connected or electrically connected, and it may include a case in which substantially integral parts are connected to each other although they may be referred to by different names according to positions or functions.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

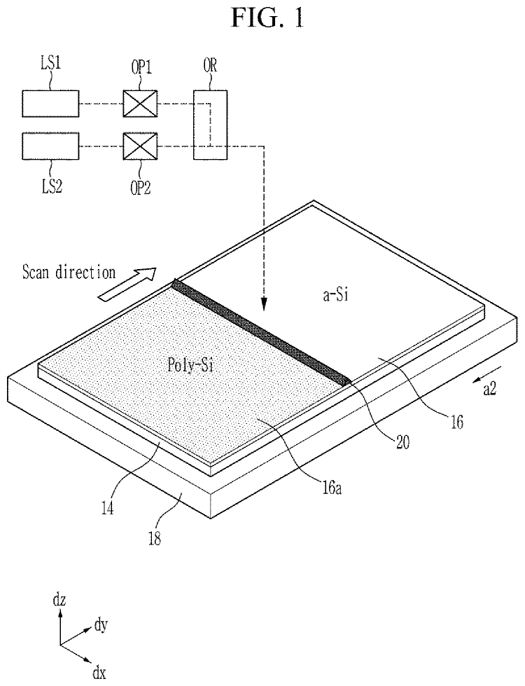

Referring to FIG. 1 to FIG. 5, a crystallization apparatus according to an embodiment will be described.

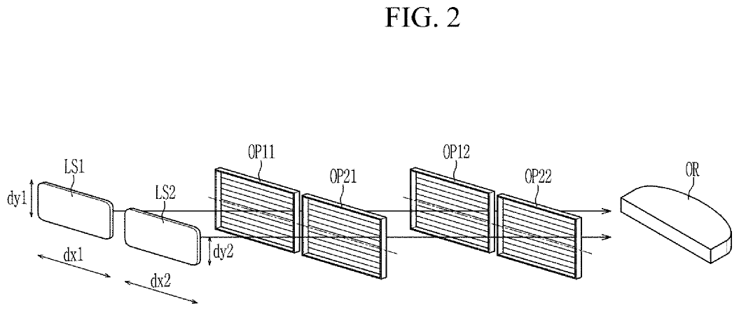

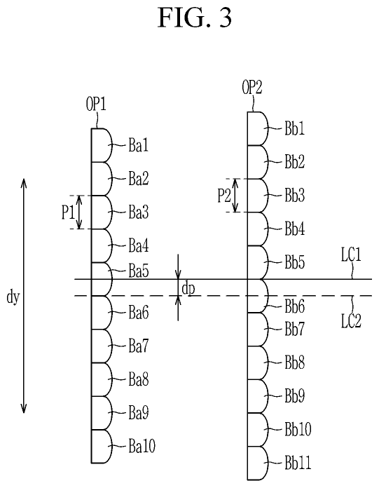

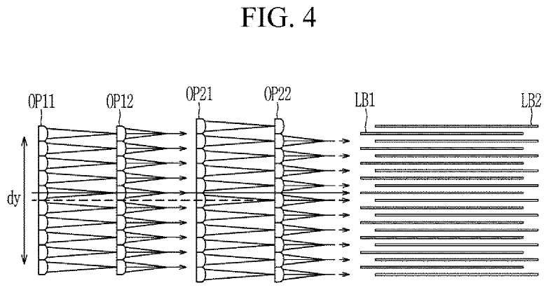

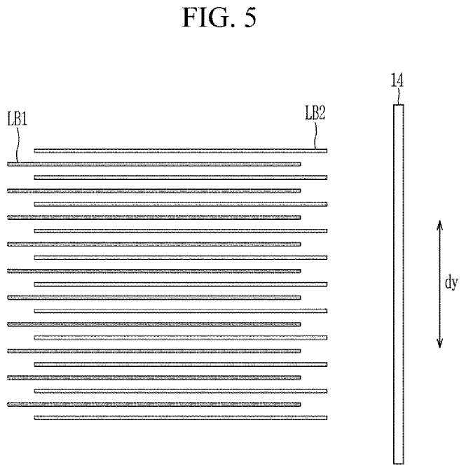

FIG. 1 is a schematic perspective view of a laser crystallization apparatus according to an embodiment, and FIG. 2 shows a part of the laser crystallization apparatus of FIG. 1. FIG. 3 shows an optical path conversion member and an optical path of the laser crystallization apparatus according to an embodiment, and FIG. 4 shows a portion of the optical path conversion member of the laser crystallization apparatus according to an embodiment. FIG. 5 shows a path of the laser beam having passed through the laser crystallization apparatus according to an embodiment.

In FIG. 1, a laser crystallization apparatus according to an embodiment may include a plurality of light sources LS1 and LS2, a plurality of beam homogenizers OP1 and OP2, an optical system or array OR that combines a plurality of laser beams, and a transfer stage 18.

Along a third direction dz, a substrate 14 that may include an amorphous silicon thin film 16 may be placed on the transfer stage 18, and the amorphous silicon thin film 16 may be scanned by a line-shaped laser beam 20 irradiated from top to bottom in a direction parallel with the third direction dz, generated from the laser crystallization apparatus according to an embodiment.

The position of the laser beam 20 may be fixed, and the transfer stage 18 moves along a transfer direction a2. For example, the laser beam 20 scans the amorphous silicon thin film 16 in a scan direction of an opposite direction of the transfer direction a2 by movement of the transfer stage 18, and amorphous silicon of a scanned area 16a is melted and transformed into polysilicon through a solidification process.

The laser beam 20 may have a line shape extending in the first direction dx, and a laser beam of uniform intensity may be irradiated in the first direction dx and the second direction dy to thereby uniformly perform the crystallization process for changing amorphous silicon to polysilicon.

Although it is not illustrated, the optical system or array may include a plurality of lenses and a plurality of mirrors, and the laser beam may be scanned on the substrate 14 by changing the energy distribution and direction of the oscillated laser beam.

Referring to FIG. 2 together with FIG. 1, in the laser crystallization apparatus according to an embodiment, the first beam homogenizer OP1 through which the laser beam irradiated from the first light source LS1 may be passed may include a first lens array OP11 and a second lens array OP12 through which the laser beam irradiated from the second light source LS2 may be passed, and may include a third lens array OP21 and a fourth lens array OP22.

The first light source LS1 may irradiate a laser having a first width dx1 and a second width dy1, and the second light source LS2 may irradiate a laser having a third width dx2 and a fourth width dy2.

The first width dx1 of the laser beam irradiated from the first light source LS1 may be larger than the second width dy1, and the laser beam irradiated in a direction parallel with the first width dx1 may be irradiated in the first direction dx of the line-type laser beam 20, and light irradiated in a direction parallel with the second width dy1 may be irradiated in the second direction dy of the line-type laser beam 20. Similarly, the third width dx2 of the laser beam irradiated from the second light source LS2 may be larger than the fourth width dy2, the laser beam irradiated in a direction parallel with the third width dx2 may be irradiated in the first direction dx of the line-type laser beam 20, and the laser beam irradiated in a direction parallel with the fourth width dy2 may be irradiated in the second direction dy of the line-type laser beam 20.

As described, the laser beams irradiated from the first light source LS1 and the second light source LS2 are irradiated together on the substrate 14, and thus, even in case that a path of the laser beam 20 is transformed into a line having a relatively long length along the first direction dx and irradiated, it is possible to prevent the intensity of the laser beam 20 from decreasing in a direction parallel to the first direction dx.

The laser beam irradiated from the first light source LS1 may pass through the first lens array OP11 that may include a plurality of lenses arranged or disposed in a direction parallel with the second width dy1 and a second lens array OP12 that may include a plurality of lenses arranged or disposed in the direction parallel with the second width dy1 such that laser beams having uniform intensity may be irradiated in a direction parallel with the second direction dy. Similarly, the laser beam irradiated from the second light source LS2 may pass through a third lens array OP21 that may include a plurality of lenses arranged or disposed in a direction parallel with the fourth width dy2 and a fourth lens array OP22 that may include a plurality of lenses arranged or disposed in the direction parallel with the fourth width dy2 such that laser beams having a uniform intensity may be irradiated in a direction parallel with the second direction dy.

The plurality of lenses included in the first lens array OP11, the second lens array OP12, the third lens array OP21, and the fourth lens array OP22 may be cylindrical lenses that extend in a direction parallel with a long axis direction, which is parallel with the first width dx1 and the third width dx2 of the first light source LS1 and the second light source LS2. However, the disclosure is not limited thereto.

The plurality of lenses included in the first lens array OP11, the second lens array OP12, the third lens array OP21, and the fourth lens array OP22 may be different from each other in shape and arrangement.

Referring to FIG. 3, shapes and alignments of a plurality of lenses of a first lens array OP11, a second lens array OP12, a third lens array OP21, and a fourth lens array OP22 will be described.

In FIG. 3, a first lens array OP11 of the first beam homogenizer OP1 and a third lens array OP21 of the second beam homogenizer OP2 are illustrated.

Referring to FIG. 3, the first lens array OP11 of the first beam homogenizer OP1 may include a plurality of first lenses Ba1, Bat, Ba3, Ba4, Ba5, Ba6, Ba1, Bab, Ba9, and Ba10 that may be arranged or disposed in a short-axis direction dy parallel with the second width dy1 and the fourth width dy2 of the first light source LS1 and the second light source LS2. The plurality of first lenses Ba1, Ba2, Ba3, Ba4, Ba5, Ba6, Ba7, Ba8, Ba9, and Ba10 may be arranged or disposed to have a first pitch P1. Although it is not illustrated, the second lens array OP12 of the first beam homogenizer OP1 may have the same shape and alignment or substantially the same shape and alignment as the first lens array OP11 of the first beam homogenizer OP1.

Similarly, the third lens array OP21 of the second beam homogenizer OP2 may include a plurality of second lenses Bb1, Bb2, Bb3, Bb4, Bb5, Bb6, Bb7, Bb8, Bb9, Bb10, and Bb11 that may be arranged or disposed in the direction dy parallel with the second width dy1 and the fourth width dy2 of the first light source LS1 and the second light source LS2. The plurality of second lenses Bb1, Bb2, Bb3, Bb4, Bb5, Bb6, Bb7, Bb8, Bb9, Bb10, and Bb11 may be arranged or disposed to have a second pitch P2. Although it is not illustrated, the fourth lens array OP22 of the second beam homogenizer OP2 may also have the same shape and alignment or substantially the same shape and alignment as the third lens array OP21 of the second beam homogenizer OP2.

The first pitch P1 of the plurality of first lenses Ba1, Ba2, Ba3, Ba4, Ba5, Ba6, Ba7, Ba8, Ba9, and Ba10 of the first beam homogenizer OP1 and the second pitch P2 of the plurality of second lenses Bb1, Bb2, Bb3, Bb4, Bb5, Bb6, Bb7, Bb8, Bb9, Bb10, and Bb1l of the second beam homogenizer OP2 may be the same. However, a first central axis LC1 of each of the plurality of first lenses Ba1, Ba2, Ba3, Ba4, Ba5, Ba6, Ba7, Ba8, Ba9, and Ba10 of the first beam homogenizer OP1 may be shifted by a first interval gap dp in the short axis direction dy rather than being disposed in line with a second central axis LC2 of each of the plurality of second lenses Bb1, Bb2, Bb3, Bb4, Bb5, Bb6, Bb7, Bb8, Bb9, Bb10, and Bb1l of the second beam homogenizer OP2. The first interval gap dp may be smaller than the first pitch P1 and the second pitch P2, and for example, may be the same as about the half the first pitch P1 and the second pitch P2.

The number of the plurality of first lenses Ba1, Ba2, Ba3, Ba4, Ba5, Ba6, Ba7, Ba8, Ba9, and Ba10 of the first beam homogenizer OP1 and the number of the plurality of second lenses Bb1, Bb2, Bb3, Bb4, Bb5, Bb6, Bb7, Bb8, Bb9, Bb10, and Bb11 of the second beam homogenizer OP2 may be different from each other.

A difference between the number of the plurality of first lenses Ba1, Ba2, Ba3, Ba4, Ba5, Ba6, Ba7, Ba8, Ba9, and Ba10 of the first beam homogenizer OP1 and the number of the plurality of second lenses Bb1, Bb2, Bb3, Bb4, Bb5, Bb6, Bb7, Bb8, Bb9, Bb10, and Bb11 of the second beam homogenizer OP2 may be 1. For example, the number of the plurality of first lenses Ba1, Ba2, Ba3, Ba4, Ba5, Ba6, Ba7, Ba8, Ba9, and Ba10 of the first beam homogenizer OP1 may be even-numbered, and the number of the plurality of second lenses Bb1, Bb2, Bb3, Bb4, Bb5, Bb6, Bb7, Bb8, Bb9, Bb10, and Bb11 of the second beam homogenizer OP2 may be odd-numbered. On the contrary, the number of the plurality of first lenses Ba1, Ba2, Ba3, Ba4, Ba5, Ba6, Ba7, Ba8, Ba9, and Ba10 of the first beam homogenizer OP1 may be odd-numbered, and the number of the plurality of second lenses Bb1, Bb2, Bb3, Bb4, Bb5, Bb6, Bb7, Bb8, Bb9, Bb10, and Bb11 of the second beam homogenizer OP2 may be even-numbered.

In the illustrated embodiment, the first lens array OP11 of the first beam homogenizer OP1 may include ten first lenses Ba1, Ba2, Ba3, Ba4, Ba5, Ba6, Ba7, Ba8, Ba9, and Ba10, and the second beam homogenizer OP2 may include eleven second lenses Bb1, Bb2, Bb3, Bb4, Bb5, Bb6, Bb7, Bb8, Bb9, Bb10, and Bb11, but this is just an example, and embodiments are not limited thereto.

The plurality of first lenses Ba1, Ba2, Ba3, Ba4, Ba5, Ba6, Ba7, Ba8, Ba9, and Ba10 and the plurality of second lenses Bb1, Bb2, Bb3, Bb4, Bb5, Bb6, Bb7, Bb8, Bb9, Bb10, and Bb11 may be cylindrical lenses that extend in a direction parallel with a long-axis direction parallel with the first width dx1 and the third width dx2 of the first light source LS1 and the second light source LS2.

Referring to FIG. 4, a path of the laser beam having passed through the beam homogenizer of the laser crystallization apparatus will be described.

Referring to FIG. 4, together with FIG. 3, first pitches P1 of the plurality of first lenses Ba1, Ba2, Ba3, Ba4, Ba5, Ba6, Ba7, Ba8, Ba9, and Ba10 of the first lens array OP11 and the second lens array OP12 of the first beam homogenizer OP1, and second pitches P2 of the plurality of second lenses Bb1, Bb2, Bb3, Bb4, Bb5, Bb6, Bb7, Bb8, Bb9, Bb10, and Bb11 of the third lens array OP21 and the fourth lens array OP22 of the second beam homogenizer OP2, are equivalent to or the same as each other, but the number of plurality of first lenses Ba1, Ba2, Ba3, Ba4, Ba5, Ba6, Ba7, Ba8, Ba9, and Ba10 and the number of second lenses Bb1, Bb2, Bb3, Bb4, Bb5, Bb6, Bb7, Bb8, Bb9, Bb10, and Bb11 may be different from each other.

A first central axis LC1 of the plurality of first lenses Ba1, Bat, Ba3, Ba4, Ba5, Ba6, Ba1, Bab, Ba9, and Ba10 of the first lens array OP11 and the second lens array OP12 of the first beam homogenizer OP1, and a second central axis LC2 of the plurality of second lenses Bb1, Bb2, Bb3, Bb4, Bb5, Bb6, Bb7, Bb8, Bb9, Bb10, and Bb11 of the third lens array OP21 and the fourth lens array OP22 of the second beam homogenizer OP2, may not be aligned in a line, but they may be aligned to be different by as much as a first interval gap dp in a short-axis direction dy. The first interval gap dp may be smaller than the first pitch P1 and the second pitch P2, and for example, may be about the half the first pitch P1 and the second pitch P2.

As described, since the first beam homogenizer OP1 and the second beam homogenizer OP2 may include a plurality of lenses arranged or disposed such that central axes may be aligned while having a first interval gap dp, as shown in FIG. 5, the first laser beam path LB1 of the first laser beam of the first light source LS1, having passed through the first beam homogenizer OP1, and the second laser beam path LB2 of the second laser beam of the second light source LS2, having passed through the second beam homogenizer OP2, may be irradiated to a surface of a substrate 14 along paths that may be different from each other with reference to a second direction dy, which is a short-axis direction of a line-type laser beam 20.

Thus, compared to a case in which the first laser beam path LB1 and the second laser beam path LB2 match each other, a difference in intensity of the laser beam can be reduced along the second direction dy of the surface of the substrate 14 and the uniformity of the laser beam can be increased.

In case that vibration in the first beam homogenizer OP1 and the second beam homogenizer OP2 is affected due to external influences, or in case that a profile abnormality occurs, the influences due to vibration and profile abnormality may occur in the same positions by the first laser beam of the first light source LS1 and the second laser beam of the second light source LS2 if the first laser beam path LB1 and the second laser beam path LB2 match each other, and accordingly, laser crystallization also occurs in the same position such that they may be visually recognized as streaks or other stains in a final display device.

However, in the laser crystallization apparatus according to an embodiment, the first beam homogenizer OP1 and the second beam homogenizer OP2 include a plurality of lenses that may be arranged or disposed to have the same pitches P1 and P2, but the central axes may be misaligned by the first interval gap dp, and thus the first laser beam path LB1 of the first laser beam of the first light source LS1, having passed through the first beam homogenizer OP1 and the second laser beam path LB2 of the second laser beam of the second light source LS2, having passed through the second beam homogenizer OP2, may be different from each other with reference to the short-axis direction dy, and accordingly, even though vibration is affected due to external influences or abnormality occurs in the profile, the effects of the first laser beam of the first light source LS1 or the second laser beam of the second light source LS2 are applied to different positions such that errors can be reduced.

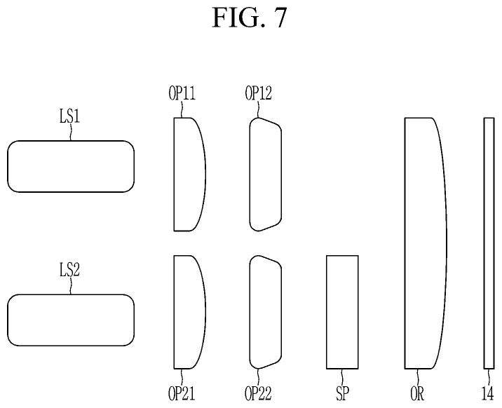

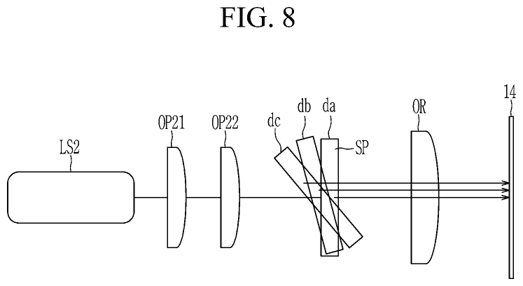

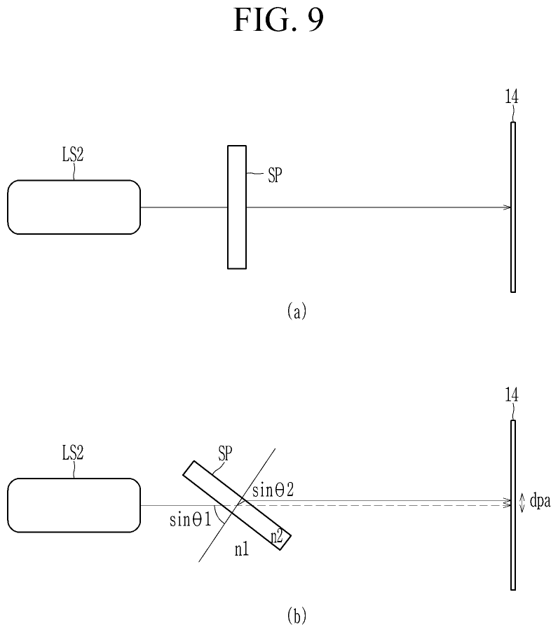

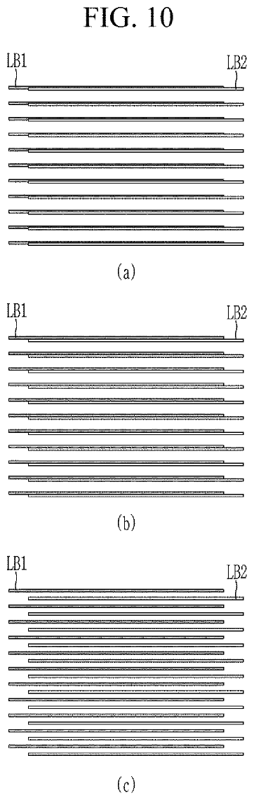

A laser crystallization apparatus according to an embodiment will be described with reference to FIG. 7 to FIGS. 10(a), (b), and (c), together with FIG. 1. FIG. 7 illustrates a part of a laser crystallization apparatus according to an embodiment. FIG. 8 and FIGS. 9 (a) and (b) show operation of a laser crystallization apparatus according to an embodiment, and FIGS. 10 (a), (b), and (c) show a path of a laser beam passing through a laser crystallization apparatus according to an embodiment.

Referring to FIG. 1 and FIG. 7, a laser crystallization apparatus according to an embodiment may include a plurality of light sources LS1 and LS2, a plurality of beam homogenizers OP1 and OP2, an optical system or array OR that combines a plurality of laser beams, and a transfer stage 18.

The first beam homogenizer OP1 through which a laser beam emitted from the first light source LS1 is passed may include a first lens array OP11 and a second lens array OP12, and the second beam homogenizer OP2 through which a laser beam emitted from the second light source LS2 may include a third lens array OP21, a fourth lens array OP22, and a path converter SP.

Referring to FIG. 8, the position of the path converter SP of the second beam homogenizer OP2 may be changed. For example, the path converter SP may be disposed in a first position da that may be almost perpendicular to an irradiation direction of the laser beam emitted from the second light source LS2, and a second position db or third direction to form a constant angle with the irradiation direction of the laser beam emitted from the second light source LS2. Depending on the positions da, db, and dc of the path converter SP, a path of the laser beam having passed through the path converter SP can be changed.

Referring to FIG. 9, in (a), in case that the path converter SP is disposed in the first position da such that the surface of the path converter SP is almost perpendicular to the irradiation direction of the laser beam emitted from the second light source LS2, the irradiation direction of the laser beam emitted from the second light source LS2 may be hardly changed even though the laser beam has passed through the path converter SP.

Referring to (b) in FIG. 9, in case that the path converter SP is disposed in the second position db or the third position dc such that the surface of the path converter SP is disposed to form a constant angle with the irradiation direction of the laser beam emitted from the second light source LS2, a path of light having passed through the path converter SP may be changed due to a refractive index of the path converter SP. According to Snell's law of refraction, according to a refractive index n1 of air and a refractive index n2 of the path converter SP, a path of the light incident on the path converter SP may be changed to satisfy a relationship equation of n1 sin θ1=n2 sin θ2.

Thus, the path of the laser beam having passed through the path converter SP can be changed by adjusting the angle formed by the irradiation direction of the laser beam emitted from the second light source LS2 and the surface of the path converter SP.

In FIGS. 10(a), (b), and (c), an example of a second laser beam path LB2 of a second laser beam of the second light source LS2, having passed through the path converter SP according to the positions da, db, and dc of the path converter SP of FIGS. 9 (a) and (b), is shown. In FIG. 10, (a) shows an example of the second laser beam path LB2 in case that the path converter SP is disposed in the position da, (b) shows an example of the second laser beam path LB2 in case that the path converter SP is disposed in the position db, and (c) shows an example of the second laser beam path LB2 in case that the path converter SP is disposed in the position dc.

Referring to (a) in FIG. 10, in case that the path converter SP is disposed in the first position da such that the surface of the path converter SP is almost perpendicular to the irradiation direction of the laser beam emitted from the second light source LS2, the irradiation direction of the laser beam emitted from the second light source LS2 may be hardly changed even though the laser beam has passed through the path converter SP, and the second laser beam path LB2 of the second laser beam of the second light source LS2 may be almost the same as the first laser beam path LB1 of the first laser beam of the first light source LS1.

Referring to (b) and (c) in FIG. 10, the second laser beam path LB2 of the second light source LS2 and the first laser beam path LB1 of the first light source LS1 become different from each other by adjusting an angle formed by the surface of the path converter SP and the irradiation direction of the laser beam emitted from the second light source LS2 is adjusted.

As described, the difference in intensity of the laser beam may be reduced and the uniformity of the laser beam may be increased by adjusting the first laser beam path LB1 of the first laser beam of the first light source LS1 and the second laser beam path LB2 of the second laser beam of the second light source LS2 to be different from each other.

Although vibration is affected due to external influences or a profile abnormality occurs, the effect of the first laser beam of the first light source LS1 or the second laser beam of the second light source LS2 is applied to different positions, thereby reducing errors in the laser beam.

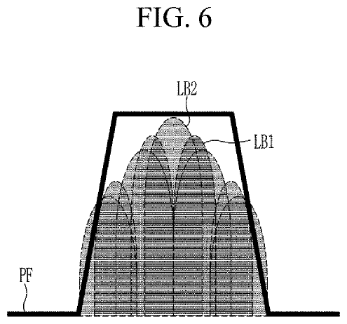

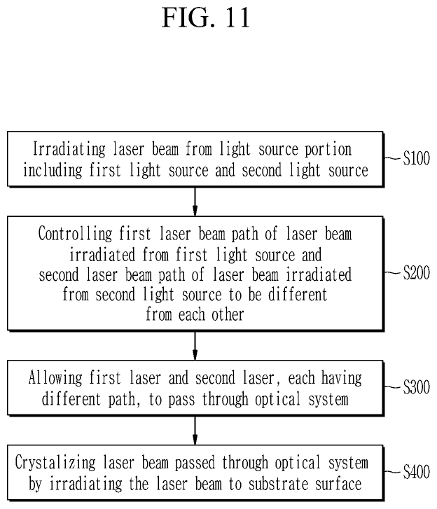

Referring to FIG. 11, together with FIG. 1 to FIGS. 10(a), (b), and (c), a laser crystallization method according to an embodiment will be described. FIG. 11 shows a laser crystallization method according to an embodiment.

Referring to FIG. 11, a laser crystallization method according to an embodiment may include irradiating a laser from a light source portion including a first light source and a second light source (S100).

The first light source LS1 may irradiate a laser beam having a first width dx1 and a second width dy1, and the second light source LS2 may irradiate a laser beam having a third width dx2 and a fourth width dy2.

The first width dx1 of the laser beam irradiated from the first light source LS1 may be larger than the second width dy1, the laser beam irradiated in a direction parallel with the first width dx1 is irradiated in a first direction dx of a line-type laser beam 20, and light irradiated in a direction parallel with the second width dy1 is irradiated in a second direction dy of the line-type laser beam 20. Similarly, the third width dx2 of the laser beam irradiated from the second light source LS2 may be larger than the fourth width dy2, the laser beam is irradiated in the first direction dx of the line-type laser beam 20, and the laser beam irradiated in a direction parallel with the fourth width dy2 is irradiated in the second direction dy of the line-type laser beam 20.

A first laser beam path LB1 and a second laser beam path LB2 of the laser beam irradiated from the light source portion may be adjusted to be different from each other (S200).

Similar to the laser crystallization apparatus according to an embodiment shown in FIG. 2 to FIG. 6, the laser beams irradiated from the light source portion including the first light source and the second light source may be arranged or disposed to have the same pitches P1 and P2, but the laser beams may be set to pass through a first beam homogenizer OP1 and a second beam homogenizer OP2, each including a plurality of lenses that may be arranged or disposed such that central axes may be aligned while having a first interval gap dp. Similar to the laser crystallization apparatus according to an embodiment shown in FIG. 7 to FIGS. 10(a), (b), and (c), the position of the path converter SP of the second beam homogenizer OP2 may be adjusted, and the laser beam irradiated from the second light source may be set to pass through the path converter SP of the second beam homogenizer OP2.

A first laser beam and a second laser beam, each having a different path, may be passed through an optical system or array OR (S300), and the laser beam having passed through the optical system or array OR may be irradiated to a substrate surface (S400).

As described, according to the laser crystallization method of an embodiment, the first laser beam path LB1 and the second laser beam path LB2 of the laser beam irradiated from the light source portion may be adjusted to be different from each other (S200), a laser beam having uniform intensity can be irradiated, and even though a vibration affects due to an external influence or a profile abnormality occurs, the effect of an error can be reduced.

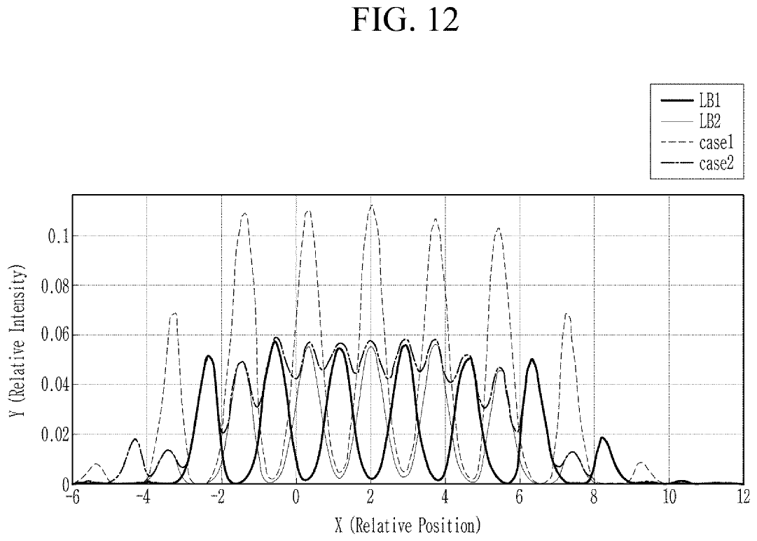

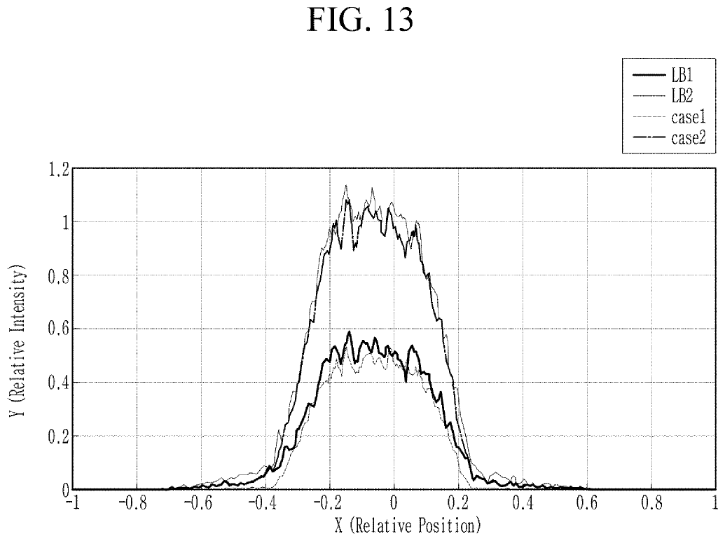

An experimental example will be described with reference to FIG. 12 and FIG. 13. FIG. 12 and FIG. 13 are graphs illustrating results of the experimental example.

In an experimental example, profile and intensity of laser beams in a first case in which a first laser beam path LB1 of a laser beam having passed through a first beam homogenizer OP1 and a second laser beam path LB2 of a laser beam having passed through a second beam homogenizer OP2 are set to be the same as in a related art case, and in a second case in which a first laser beam path LB1 of a laser beam having passed through a first beam homogenizer OP1 and a second laser beam path LB2 of a laser beam having passed through a second beam homogenizer OP2 are different from each other, and the profile and the intensity of each of the first laser beam of a first light source LS1 and a second laser beam of a second light source LS2 are illustrated in the graphs.

FIG. 12 is a graph of the profile of the laser beam, and FIG. 13 is a graph of intensity of the laser beam. In FIG. 12 and FIG. 13, a result of the first laser beam is illustrated as L1, a result of the second laser beam is illustrated as L2, a result of the first case is illustrated as case1, and a result of the second case is illustrated as case2.

Referring to FIG. 12 and FIG. 13, compared to the first case case1, which is a related art case, according to the second case case2, which is the laser crystallization apparatus and the laser crystallization method according to an embodiment, the difference in the laser beam profile was not large depending on the position, and thus it can be determined that the laser beam was uniform, and the laser beam intensity was almost the same.

Referring to Table 1, another experimental example will be described. In an experimental example, as in the related art case, the dispersion of each laser beam was measured at first and third positions, which are both ends of the line-type laser beam, and at a second position, which is a center portion of the line-type laser beam with respect to a first case in which a first laser beam path LB1 of a laser beam having passed through a first beam homogenizer OP1 and a second laser beam path LB2 of a laser beam having passed through a second beam homogenizer OP2 are set to be the same as in the related art case, and in a second case in which a first laser beam path LB1 of a laser beam having passed through a first beam homogenizer OP1 and a second laser beam path LB2 of a laser beam having passed through a second beam homogenizer OP2 are different from each other, and results are shown in Table 1.

TABLE 1

| Case | First position | Second position | Third position |
|---|---|---|---|
| Case 1 | 0.235 | 0.3653 | 0.2419 |
| Case 2 | 0.1207 | 0.2314 | 0.2311 |
| Improvement rate | 48.6% | 36.7% | 4.5% |

Referring to Table 1, compared to the first case case1 as in the related art case, it can be determined that the difference in the dispersion of the laser beam was decreased by more than about 30% according to the second case case2 such as in the laser crystallization apparatus and laser crystallization method of an embodiment. While this disclosure has been described in connection with what is considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A laser crystallization apparatus comprising:
a plurality of light sources that emit a first laser beam and a second laser beam;
a first beam homogenizer through which the first laser beam passes;
a second beam homogenizer through which the second laser beam passes; and
an optical array on which the first laser beam passed through the first beam homogenizer and the second laser beam passed through the second beam homogenizer are incident, wherein
a first path of the first laser beam passed through the first beam homogenizer and a second path of the second laser beam passed through the second beam homogenizer are different from each other,
the first beam homogenizer comprises first lenses disposed to have a first pitch along a first direction,
the second beam homogenizer comprises second lenses disposed to have a second pitch along the first direction, and
the first pitch of the first lenses and the second pitch of the second lenses are same each other.

2. The laser crystallization apparatus of claim 1, wherein a number of the first lenses and a number of the second lenses are different from each other.

3. The laser crystallization apparatus of claim 2, wherein
one of the number of the first lenses and the number of the second lenses is an odd number, and
the other of the number of the first lenses and the number of the second lenses is an even number.

4. The laser crystallization apparatus of claim 3, wherein a difference between the number of the first lenses and the number of the second lenses is one.

5. The laser crystallization apparatus of claim 4, wherein a central axis of each of the first lenses and a central axis of each of the second lenses are different from each other.

6. The laser crystallization apparatus of claim 5, wherein a difference between the central axis of the first lenses and the central axis of the second lenses is less than the first pitch of the first lenses.

7. The laser crystallization apparatus of claim 1, wherein the central axis of the first lenses is different from the central axis of the second lenses.

8. The laser crystallization apparatus of claim 7, wherein a difference between the central axis of the first lenses and the central axis of the second lenses is less than the first pitch of the first lenses.

9. A laser crystallization apparatus comprising:
a plurality of light sources that emit a first laser beam and a second laser beam;
a first beam homogenizer through which the first laser beam passes;
a second beam homogenizer through which the second laser beam passes; and
an optical array on which the first laser beam passed through the first beam homogenizer and the second laser beam passed through the second beam homogenizer are incident, wherein
a first path of the first laser beam passed through the first beam homogenizer and a second path of the second laser beam passed through the second beam homogenizer are different from each other,
the first beam homogenizer comprises a first lenses disposed along a first direction, and
the second beam homogenizer comprises a second lenses disposed along a second direction, and a path converter.

10. The laser crystallization apparatus of claim 9, wherein
the first lenses are disposed to have a first pitch,
the second lenses are disposed to have a second pitch, and
the first pitch of the first lenses and the second pitch of the second lenses are same each other.

11. The laser crystallization apparatus of claim 10, wherein a surface of the path converter is aligned to form a constant angle with a path of the second laser beam.

12. A laser beam crystallization method comprising:
irradiating a laser beam from light sources that include a first light source and a second light source;
adjusting a first path of a first laser beam irradiated from the first light source to be different from a second path of a second laser beam irradiated from the second light source; and
controlling the first laser beam having passed through a first beam homogenizer and the second laser beam having passed through a second beam homogenizer to be incident upon an optical array.

13. The laser beam crystallization method of claim 12, wherein the adjusting of the first path of the first laser beam and the second path of the second laser beam to be different from each other comprises:
controlling the first laser beam to pass through the first beam homogenizer that includes first lenses disposed to have a first pitch along a first direction; and
controlling the second laser beam to pass through the second beam homogenizer that includes second lenses disposed to have a second pitch along a second direction,
wherein the first pitch of the first lenses and the second pitch of the second lenses are same each other.

14. The laser beam crystallization method of claim 13, wherein
the controlling of the first laser beam to pass through the first beam homogenizer comprises controlling the first laser beam to pass through a first number of the first lenses, and
the controlling of the second laser beam to pass through the second beam homogenizer comprises controlling the second laser beam to pass through a second number of the second lenses.

15. The laser beam crystallization method of claim 14, wherein
one of the first number of the first lenses and the second number of the second lenses is an odd number, and
the other of the first number of the first lenses and the second number of the second lenses is an even number.

16. The laser beam crystallization method of claim 15, wherein a difference between the first number of the first lenses and the second number of the second lenses is one.

17. The laser beam crystallization method of claim 13, wherein
the controlling of the first laser beam to pass through the first beam homogenizer comprises controlling the first laser beam to pass through the first lenses,
the controlling of the second laser beam to pass through the second beam homogenizer comprises controlling the second laser beam to pass through the second lenses, and
a central axis of each of the first lenses is different from a central axis of each of the second lenses.

18. The laser beam crystallization method of claim 17, wherein a difference between the central axis of the first lenses and the central axis of the second lenses is less than the first pitch of the first lenses.

19. The laser beam crystallization method of claim 12, wherein the adjusting of the first path of the first laser beam and the second path of the second laser beam to be different from each other comprises:
controlling the first laser beam to pass through the first beam homogenizer that includes first lenses disposed to have a first pitch along a first direction; and
controlling the second laser beam to pass through the second beam homogenizer that includes second lenses disposed to have a second pitch along the first direction, and a path converter,
wherein the first pitch of the first lenses and the second pitch of the second lenses are same each other.

20. The laser beam crystallization method of claim 19, wherein
a surface of the path converter is aligned to form a constant angle with a path of the second laser beam, and
the second laser beam passes through the path converter.
